(19) United States
(12) Patent Application Publication
(10) Pub. No.: US 2025/0227845 A1
(43) Pub. Date: Jul. 10, 2025

(54) POWER SUPPLY MODULE

(71) Applicant: CYNTEC CO., LTD., Hsinchu (TW)

(72) Inventors: Bau-Ru Lu, Hsinchu (TW); Da-Jung Chen, Hsinchu (TW); Sen-Huei Chen, Hsinchu (TW)

(73) Assignee: CYNTEC CO., LTD., Hsinchu (TW)

(21) Appl. No.: 19/011,543

(22) Filed: Jan. 6, 2025

Related U.S. Application Data
(60) Provisional application No. 63/618,396, filed on Jan. 8, 2024.

(51) Int. Cl. H05K 1/14; H01F 27/02; H01F 27/29; H02M 1/00; H05K 1/18

(52) U.S. Cl. CPC H05K 1/141; H01F 27/027; H01F 27/292; H02M 1/0064; H05K 1/181; H05K 2201/10015; H05K 2201/10166

(57) ABSTRACT

A power supply module includes at least one sub-power supply module. Each of the at least one sub-power supply module includes an upper circuit board, a lower circuit board and an inductor. The inductor is disposed between the upper circuit board and the lower circuit board. An upper surface of the inductor faces the upper circuit board and a lower surface of the inductor faces the lower circuit board. The inductor includes two primary windings and two secondary windings. Two electrodes of each of the two primary windings are respectively arranged at the upper surface and the lower surface of the inductor and respectively connected to the upper circuit board and the lower circuit board. The two secondary windings are electrically connected in series through the upper circuit board and the lower circuit board or through the upper circuit board.

### CROSS REFERENCE TO RELATED APPLICATIONS

This application claims the benefit of U.S. Provisional Application No. 63/618,396, filed on Jan. 8, 2024. The content of the application is incorporated herein by reference.

### BACKGROUND OF THE INVENTION

### 1. Field of the Invention

The invention relates to a power supply module and, more particularly, to a power supply module adapted to a vertical power delivery configuration.

### 2. Description of the Related Art

As graphics processing unit (GPU) and central processing unit (CPU) have increasingly stringent power requirements, a power module needs to meet various requirements such as wide input range, high input voltage, high output power, high efficiency, high density, small size, light weight, efficient heat dissipation, etc. At present, the power module supplies power to the GPU/CPU through a lateral power delivery (LPD) manner and some output capacitors are disposed between the GPU/CPU and the power module, such that a power distribution network (PDN) has long paths and the transient also becomes large.

### SUMMARY OF THE INVENTION

The invention provides a power supply module adapted to a vertical power delivery configuration, so as to solve the aforesaid problems.

According to an embodiment of the invention, a power supply module comprises at least one sub-power supply module. Each of the at least one sub-power supply module comprises an upper circuit board, a lower circuit board and an inductor. The lower circuit board is disposed opposite to the upper circuit board. The lower circuit board has a plurality of power electrodes disposed on a mounting surface of the lower circuit board. The plurality of power electrodes are configured to be mounted to a system board. The inductor is disposed between the upper circuit board and the lower circuit board. An upper surface of the inductor faces the upper circuit board and a lower surface of the inductor faces the lower circuit board. The inductor comprises two primary windings and two secondary windings. Two electrodes of each of the two primary windings are respectively arranged at the upper surface and the lower surface of the inductor and respectively connected to the upper circuit board and the lower circuit board. The two secondary windings are electrically connected in series through the upper circuit board and the lower circuit board or through the upper circuit board.

In an embodiment, two electrodes of each of the two secondary windings are respectively arranged at the upper surface and the lower surface of the inductor and respectively connected to the upper circuit board and the lower circuit board. The inductor further comprises two connecting members. Two ends of each of the two connecting members are respectively arranged at the upper surface and the lower surface of the inductor and respectively connected to the upper circuit board and the lower circuit board, such that the two secondary windings are electrically connected in series through the upper circuit board, the lower circuit board and the two connecting members.

In an embodiment, the two connecting members are disposed within a magnetic body of the inductor and located at two opposite sides of the magnetic body.

In an embodiment, the inductor further comprises two power conductive members and two ends of each of the two power conductive members are respectively arranged at the upper surface and the lower surface of the inductor.

In an embodiment, the two power conductive members are disposed within a magnetic body of the inductor and located at two opposite sides of the magnetic body.

In an embodiment, the power supply module comprises a plurality of sub-power supply modules, wherein the lower circuit boards of the plurality of sub-power supply modules are integrated to be one single lower circuit board and the upper circuit boards of the plurality of sub-power supply modules are separated from each other.

In an embodiment, two electrodes of each of the two secondary windings are arranged at the upper surface of the inductor and connected to the upper circuit board, such that the two secondary windings are electrically connected in series through the upper circuit board.

In an embodiment, the power supply module comprises at least one control electrode configured to receive control signals from a power component on the upper circuit board through a signal connecting structure.

In an embodiment, the power supply module comprises a power controller disposed on the upper circuit board, the power controller transmits control signals to a power component on the upper circuit board through the upper circuit board, there is no control electrode disposed on the lower circuit board, and the control signals are only transmitted through the upper circuit board.

In an embodiment, the inductor is a symmetrical structure.

In an embodiment, two power switches are disposed on the upper circuit board, and the two power switches are connected in series at a switch pad to form a half bridge power component or a full bridge power component.

In an embodiment, the switch pad is electrically connected to one of the two electrodes of the primary winding arranged at the upper surface of the inductor, the other one of the two electrodes of the primary winding arranged at the lower surface of the inductor is electrically connected to an output electrode of the lower circuit board, and one of the two primary windings and one of the two power switches form one-phase power output.

In an embodiment, the power supply module further comprises a plurality of output capacitors, wherein the lower surface of the inductor has a recess configured to accommodate the plurality of output capacitors.

In an embodiment, the power supply module further comprises a plurality of input capacitors embedded in the upper surface of the inductor.

In an embodiment, the lower circuit board is equipped with a plurality of output capacitors without input capacitors and the upper circuit board is equipped with a plurality of input capacitors without output capacitors.

According to an embodiment of the invention, a power supply module comprises at least one sub-power supply module. Each of the at least one sub-power supply module comprises an upper circuit board, a lower circuit board and an inductor. The lower circuit board is disposed opposite to the upper circuit board. The lower circuit board has a plurality of power electrodes disposed on a mounting surface of the lower circuit board. The plurality of power electrodes are configured to be mounted to a system board. The inductor is disposed between the upper circuit board and the lower circuit board. An upper surface of the inductor faces the upper circuit board and a lower surface of the inductor faces the lower circuit board. The inductor comprises two primary windings and two secondary windings. Two electrodes of each of the two primary windings are respectively arranged at the upper surface and the lower surface of the inductor and respectively connected to the upper circuit board and the lower circuit board. Two electrodes of each of the two secondary windings are arranged at the lower surface of the inductor and connected to the lower circuit board, such that the two secondary windings are electrically connected in series through the lower circuit board and the system board.

In an embodiment, a plurality of output capacitors are embedded in the lower circuit board.

As mentioned in the above, two electrodes of each of the two primary windings are respectively arranged at the upper surface and the lower surface of the inductor and respectively connected to the upper circuit board and the lower circuit board, such that the power component on the upper circuit board may deliver power to the system board connected with the lower circuit board. In one embodiment, the two secondary windings may be electrically connected in series through the upper circuit board and the lower circuit board or through the upper circuit board. In another embodiment, the two secondary windings may be electrically connected in series through the lower circuit board and the system board. Through the aforesaid configuration, the two primary windings and the two power switches may form two-phase power output. Accordingly, the power supply module of the invention can be stacked with the system board by a vertical power delivery configuration, so as to reduce the path of the power distribution network (PDN) and the transient. Since the power supply module is stacked with the system board, the power delivery path is minimized to reduce the parasitic inductance and the size of the system board can also be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a power supply module according to an embodiment of the invention.

FIG. 2 is an exploded view illustrating the power supply module shown in FIG. 1.

FIG. 3 is an exploded view illustrating a sub-power supply module shown in FIG. 1.

FIG. 4 is a perspective view illustrating an inductor shown in FIG. 3 from another viewing angle.

FIG. 5 is a perspective view illustrating the inductor shown in FIG. 3 without thermal conductive filler.

FIG. 6 is a schematic view illustrating partial configuration of the power supply module shown in FIG. 1.

FIG. 7 is a schematic view illustrating an equivalent circuit of the power supply module shown in FIG. 6.

FIG. 8 is a perspective view illustrating the inductor according to another embodiment of the invention.

FIG. 9 is a perspective view illustrating two primary windings and two secondary windings according to another embodiment of the invention.

FIG. 10 is a perspective view illustrating a sub-power supply module according to another embodiment of the invention.

FIG. 11 is a side view illustrating the sub-power supply module shown in FIG. 10.

FIG. 12 is a perspective view illustrating a sub-power supply module according to another embodiment of the invention.

FIG. 13 is a perspective view illustrating a sub-power supply module according to another embodiment of the invention.

FIG. 14 is a perspective view illustrating the inside of the sub-power supply module shown in FIG. 13.

FIG. 15 is a perspective view illustrating the sub-power supply module shown in FIG. 13 from another viewing angle.

FIG. 16 is a schematic view illustrating a power supply system according to an embodiment of the invention.

### DETAILED DESCRIPTION

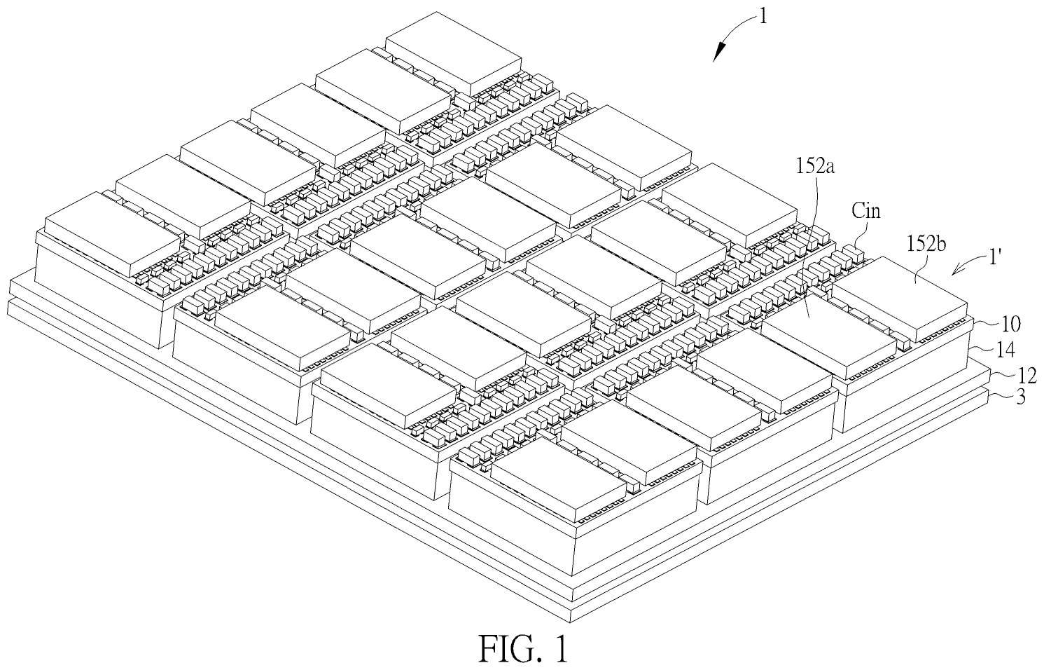

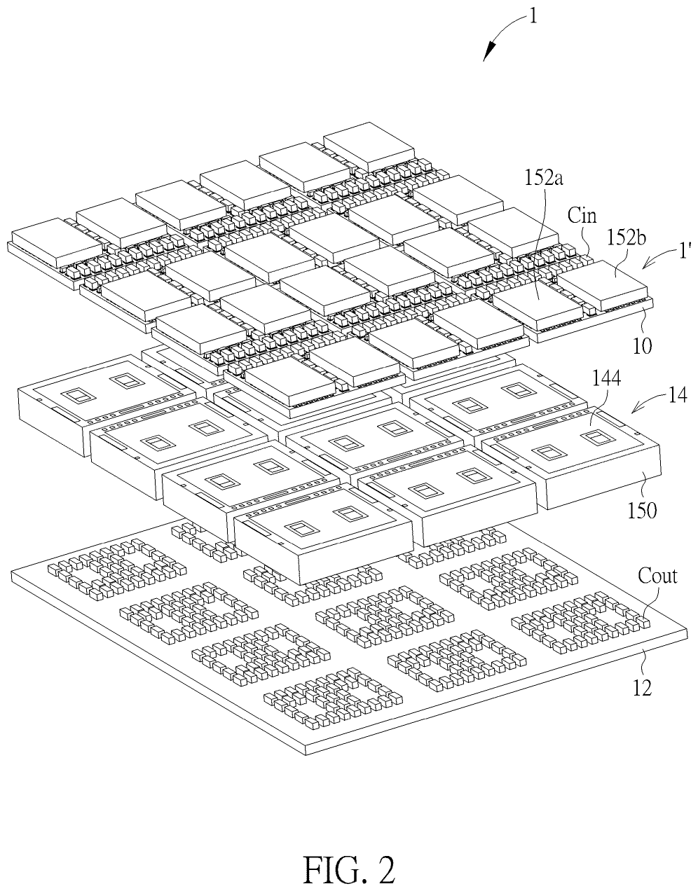

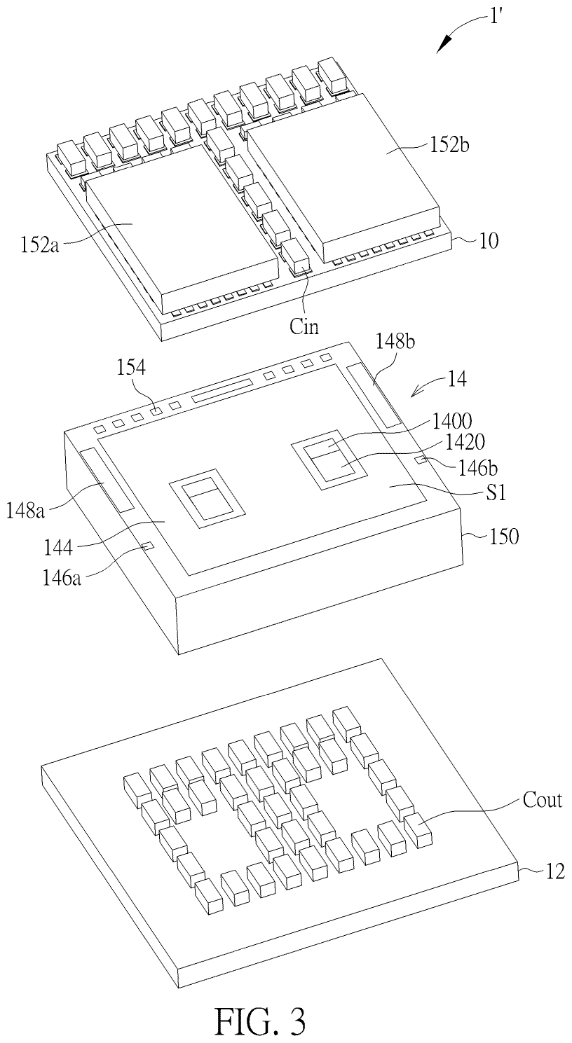

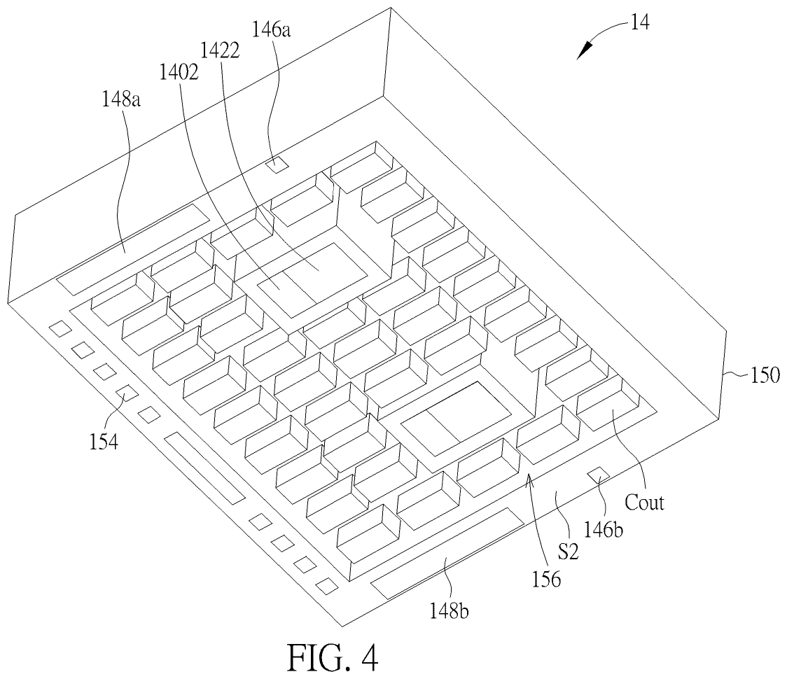

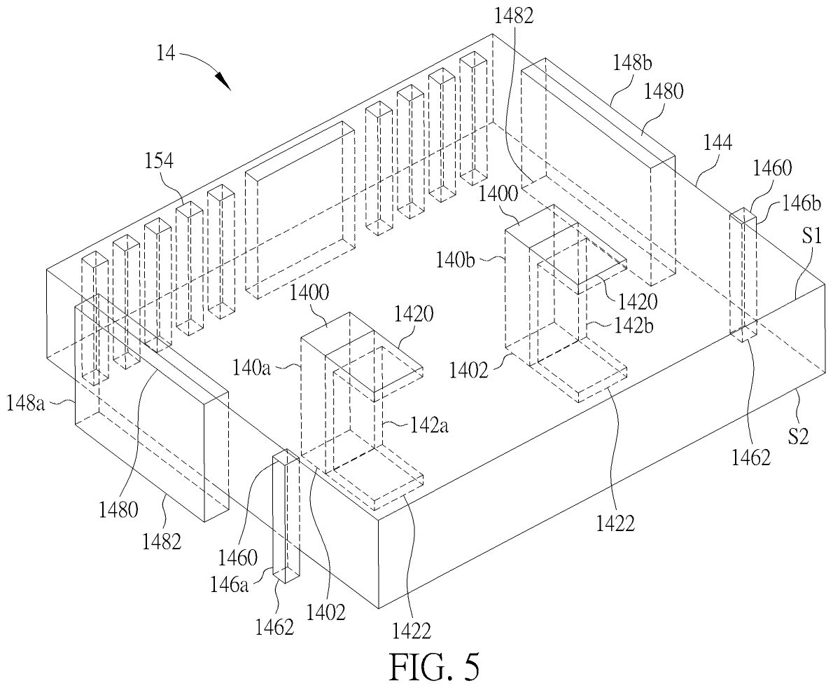

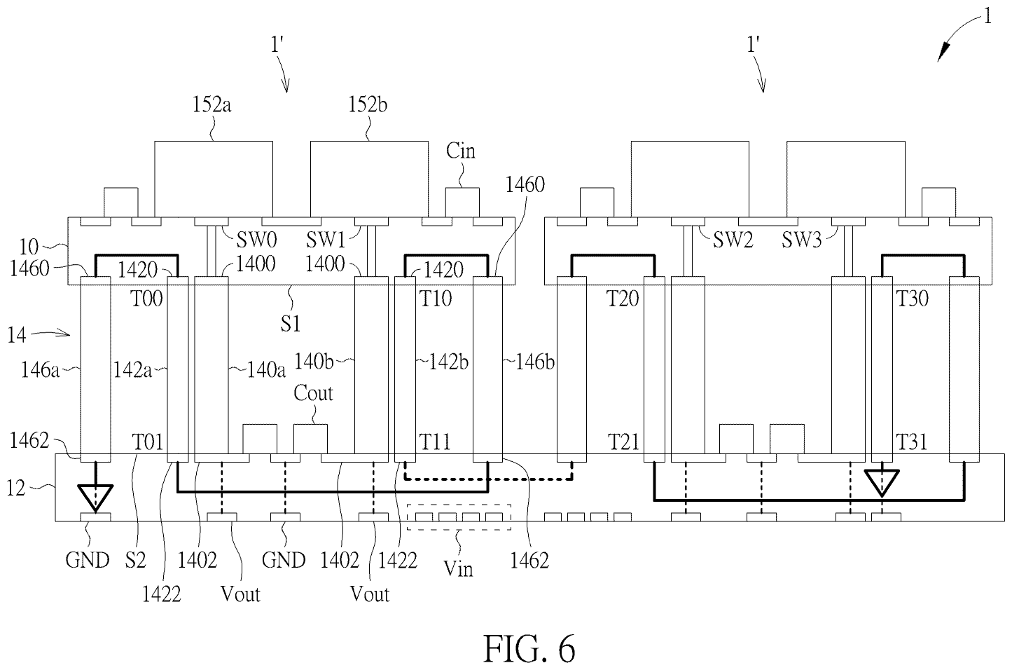

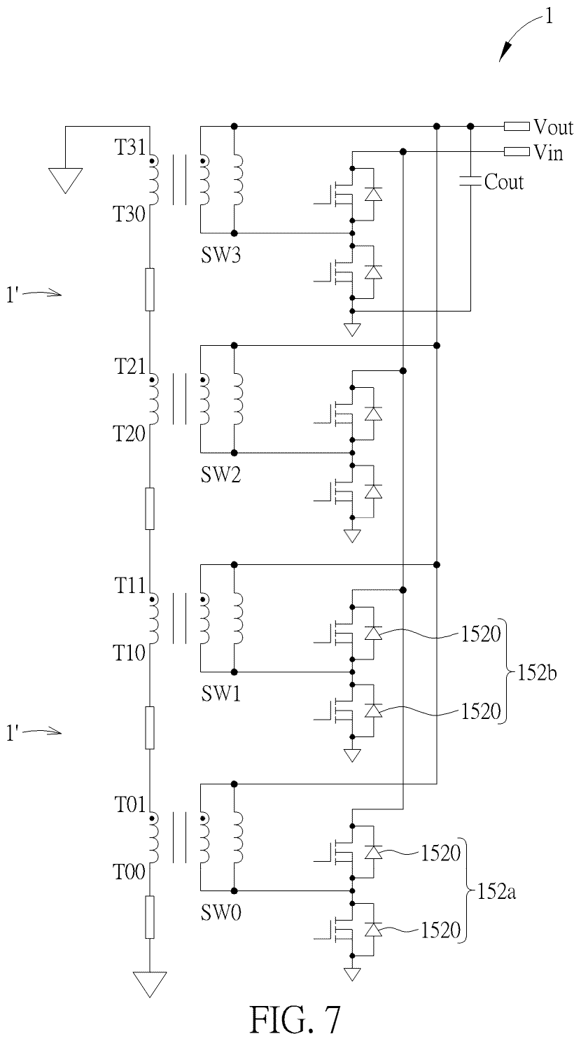

Referring to FIGS. 1 to 7, FIG. 1 is a perspective view illustrating a power supply module 1 according to an embodiment of the invention, FIG. 2 is an exploded view illustrating the power supply module 1 shown in FIG. 1, FIG. 3 is an exploded view illustrating a sub-power supply module 1′ shown in FIG. 1, FIG. 4 is a perspective view illustrating an inductor 14 shown in FIG. 3 from another viewing angle, FIG. 5 is a perspective view illustrating the inductor 14 shown in FIG. 3 without thermal conductive filler, FIG. 6 is a schematic view illustrating partial configuration of the power supply module 1 shown in FIG. 1, and FIG. 7 is a schematic view illustrating an equivalent circuit of the power supply module 1 shown in FIG. 6.

As shown in FIGS. 1 to 3, the power supply module 1 comprises at least one sub-power supply module 1′. Each of the at least one sub-power supply module 1′ comprises an upper circuit board 10, a lower circuit board 12 and an inductor 14. The lower circuit board 12 is disposed opposite to the upper circuit board 10, and the inductor 14 is disposed between the upper circuit 10 board and the lower circuit board 12. In this embodiment, the power supply module 1 may comprise a plurality of sub-power supply modules 1′, wherein the lower circuit boards 12 of the sub-power supply modules 1′ may be integrated to be one single lower circuit board 12 and the upper circuit boards 10 of the sub-power supply modules 1′ may be separated from each other. Thus, the thermal stress of the sub-power supply modules 1′ will not interfere with each other, so as to reduce the total thermal stress of the power supply module 1. However, the invention is not limited to the embodiment shown in the figure. In another embodiment, the lower circuit boards 12 of the sub-power supply modules 1′ may also be separated from each other. Furthermore, the number of sub-power supply modules 1′ may be determined according to practical applications.

As shown in FIGS. 3 to 6, an upper surface S1 of the inductor 14 faces the upper circuit board 10 and a lower surface S2 of the inductor faces the lower circuit board 12. In this embodiment, the inductor 14 may comprise two primary windings 140a, 140b and two secondary windings 142a, 142b, wherein the primary winding 140a and the secondary winding 142a form a pair of windings, and the primary winding 140b and the secondary winding 142b form another pair of windings. In practical applications, the inductor 14 may comprise a magnetic body 144 (e.g. magnetic core), wherein the upper surface S1 and the lower surface S2 may be opposite surfaces of the magnetic body 144. The two primary windings 140a, 140b and the two secondary windings 142a, 142b may be molded in the magnetic body 144. The two primary windings 140a, 140b and the two secondary windings 142a, 142b are electrically insulated within the magnetic body 144. For example, the two primary windings 140a, 140b and the two secondary windings 142a, 142b may be spaced apart or covered by an insulating layer.

Two electrodes 1400, 1402 of each of the two primary windings 142a, 142b are respectively arranged at the upper surface S1 and the lower surface S2 of the inductor 14 and respectively connected to the upper circuit board 10 and the lower circuit board 12. For further explanation, the electrode 1400 of each of the two primary windings 142a, 142b is arranged at the upper surface S1 of the inductor 14 and connected to the upper circuit board 10, and the electrode 1402 of each of the two primary windings 142a, 142b is arranged at the lower surface S2 of the inductor 14 and connected to the lower circuit board 12.

As shown in FIGS. 6 and 7, the two secondary windings 142a, 142b may be electrically connected in series through the upper circuit board 10 and the lower circuit board 12. In this embodiment, two electrodes 1420, 1422 of each of the two secondary windings 142a, 142b are respectively arranged at the upper surface S1 and the lower surface S2 of the inductor 14 and respectively connected to the upper circuit board 10 and the lower circuit board 12. For further explanation, the electrode 1420 of each of the two secondary windings 142a, 142b is arranged at the upper surface S1 of the inductor 14 and connected to the upper circuit board 10, and the electrode 1422 of each of the two secondary windings 142a, 142b is arranged at the lower surface S2 of the inductor 14 and connected to the lower circuit board 12.

In this embodiment, the inductor 14 may further comprise two connecting members 146a, 146b. Two ends 1460, 1462 of each of the two connecting members 146a, 146b are respectively arranged at the upper surface S1 and the lower surface S2 of the inductor 14 and respectively connected to the upper circuit board 10 and the lower circuit board 12. For further explanation, the end 1460 of each of the two connecting members 146a, 146b is arranged at the upper surface S1 of the inductor 14 and connected to the upper circuit board 10, and the end 1462 of each of the two connecting members 146a, 146b is arranged at the lower surface S2 of the inductor 14 and connected to the lower circuit board 12.

As shown in FIG. 6, the electrode 1420 of the secondary winding 142a may be electrically connected to the end 1460 of the connecting member 146a through the upper circuit board 10, the electrode 1422 of the secondary winding 142a may be electrically connected to the end 1462 of the connecting member 146b through the lower circuit board 12, and the electrode 1420 of the secondary winding 142b may be electrically connected to the end 1460 of the connecting member 146b through the upper circuit board 10, such that the two secondary windings 142a, 142b are electrically connected in series through the upper circuit board 10, the lower circuit board 12 and the two connecting members 146a, 146b. It should be noted that the electrode 1422 of the secondary winding 142b of one sub-power supply modules 1′ may be electrically connected to the end 1462 of the connecting member 146a of the adjacent sub-power supply modules 1′ through the lower circuit board 12, such that two adjacent sub-power supply modules 1′ are electrically connected to each other.

In this embodiment, the inductor 14 may further comprises two power conductive members 148a, 148b. Two ends 1480, 1482 of each of the two power conductive members 148a, 148b are respectively arranged at the upper surface S1 and the lower surface S2 of the inductor 14 and respectively connected to the upper circuit board 10 and the lower circuit board 12. For further explanation, the end 1480 of each of the two power conductive members 148a, 148b is arranged at the upper surface S1 of the inductor 14 and connected to the upper circuit board 10, and the end 1482 of each of the two power conductive members 148a, 148b is arranged at the lower surface S2 of the inductor 14 and connected to the lower circuit board 12.

In this embodiment, the two connecting members 146a, 146b may be disposed at two opposite sides of the inductor 14 and covered by a thermal conductive filler 150. Similarly, the two power conductive members 148a, 148b may also be disposed at two opposite sides of the inductor 14 and covered by the thermal conductive filler 150. Thus, the inductor 14 may be a symmetrical structure. There are no connecting members and power conductive members disposed at the other two opposite sides of the inductor 14, so as to simplify the manufacturing process of the inductor 14 and reduce the manufacturing cost.

In this embodiment, two power components 152a, 152b may be disposed on the upper circuit board 10. The power components 152a, 152b may be, but are not limited to Dr. MOS essentially consisting of driver IC and MOSFET (Metal-Oxide-Semiconductor Field-Effect Transistor). The sub-power supply module 1′ may comprise at least one control electrode configured to receive control signals from the two power components 152a, 152b on the upper circuit board 10 through a signal connecting structure 154. The signal connecting structure 154 may shorten the signal transmission path to stabilize the operation. Each of the two power components 152a, 152b may comprise two power switches 1520, wherein the two power switches 1520 are disposed on the upper circuit board 10 and connected in series at a switch pad to form a half bridge power component or a full bridge power component. As shown in FIG. 7, two power switches 1520 of the power component 152a of one sub-power supply module 1′ are connected in series at a switch pad SW0, two power switches 1520 of the power component 152b of one sub-power supply module 1′ are connected in series at a switch pad SW1, two power switches 1520 of the power component 152a of the other sub-power supply module 1′ are connected in series at a switch pad SW2, and two power switches 1520 of the power component 152b of the other sub-power supply module 1′ are connected in series at a switch pad SW3.

In this embodiment, the lower circuit board 12 may have a plurality of power electrodes disposed on a mounting surface of the lower circuit board 12, wherein the power electrodes are configured to be mounted to a system board 3 (as shown in FIG. 1). In practical applications, the system board 3 may be a server equipped with a central processing unit (CPU), a graphics processing unit (GPU), a random access memory (RAM), a hard disk drive (HDD), a solid state disk (SSD), a network interface, and so on. As shown in FIG. 6, the power electrodes may comprise a plurality of output electrodes Vout, a plurality of input electrodes Vin and a plurality of ground electrodes GND.

In this embodiment, the power supply module 1 may further comprises a plurality of output capacitors Cout and a plurality of input capacitors Cin. The output capacitors Cout may be disposed on the lower circuit board 12. As shown in FIG. 4, the lower surface S2 of the inductor 14 may have a recess 156 configured to accommodate the output capacitors Cout. In this embodiment, the primary windings 140a, 140b, the secondary windings 142a, 142b, the connecting members 146a, 146b and/or the power conductive members 148a, 148b may protrude from the magnetic body 144 to form the recess 156 therebetween. Furthermore, the input capacitors Cin may be disposed on the upper circuit board 10 and around the power components 152a, 152b. In this embodiment, the lower circuit board 12 may be equipped with the output capacitors Cout without input capacitors and the upper circuit board 10 may be equipped with the input capacitors Cin without output capacitors.

As shown in FIGS. 6 and 7, TO0, TO1, T10, T11, T20, T21, T30 and T31 represent a plurality of connecting points of the secondary windings 142a, 142b of two sub-power supply modules 1′. The secondary windings 142a, 142b of two sub-power supply modules 1′ are electrically connected in series through the upper circuit board 10, the lower circuit board 12 and the connecting members 146a, 146b. Furthermore, the switch pad SW0 is electrically connected to one of the two electrodes 1400, 1402 of the primary winding 140a arranged at the upper surface S1 of the inductor 14, and the other one of the two electrodes 1400, 1402 of the primary winding 140a arranged at the lower surface S2 of the inductor 14 is electrically connected to an output electrode Vout of the lower circuit board 12. It should be noted that the switch pads SW1, SW2, SW3 are respectively connected to the primary winding 140a or 140b in the same manner as the switch pad SW0, and the repeated explanation will not be depicted herein again. Thus, in one sub-power supply modules 1′, one of the two primary windings 140a, 140b and one of the two power switches 1520 form one-phase power output, such that the two primary windings 140a, 140b and the two power switches 1520 may form two-phase power output. Each phase power output may be powered in parallel by the circuit layout of the lower circuit board 12 and/or the system board 3.

Through the aforesaid configuration, the power supply module 1 of the invention can be stacked with the system board 3 by a vertical power delivery configuration, so as to reduce the path of the power distribution network (PDN) and the transient. Since the power supply module 1 is stacked with the system board 3, the power delivery path is minimized to reduce the parasitic inductance and the size of the system board 3 can also be reduced.

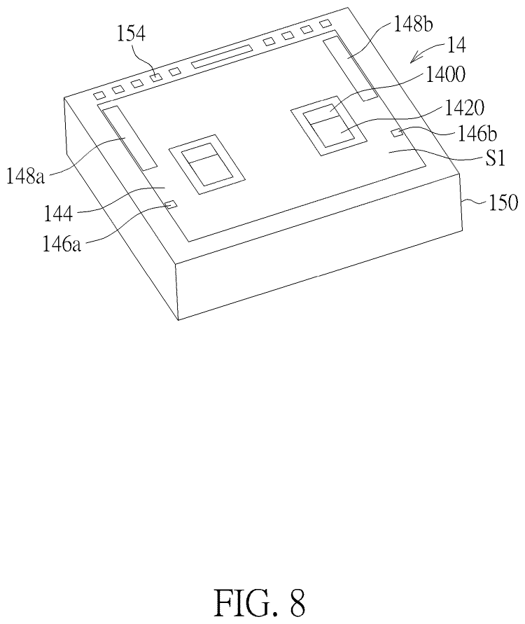

Referring to FIG. 8, FIG. 8 is a perspective view illustrating the inductor 14 according to another embodiment of the invention.

As shown in FIG. 8, the two connecting members 146a, 146b and the two power conductive members 148a, 148b may be disposed within the magnetic body 144 of the inductor 14 and located at two opposite sides of the magnetic body 144.

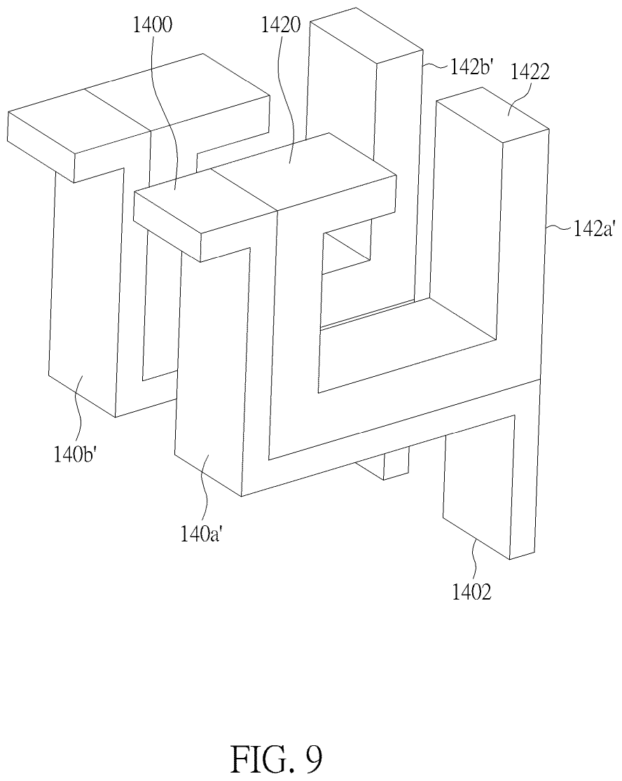

Referring to FIG. 9, FIG. 9 is a perspective view illustrating two primary windings 140a′, 140b′ and two secondary windings 142a′, 142b′ according to another embodiment of the invention.

The two primary windings 140a, 140b and the two secondary windings 142a, 142b shown in FIG. 5 may be replaced by the two primary windings 140a′, 140b′ and the two secondary windings 142a′, 142b′ shown in FIG. 9. After replacement, two electrodes 1420, 1422 of each of the two secondary windings 142a′, 142b′ are arranged at the upper surface S1 of the inductor 14 and connected to the upper circuit board 10 (as shown in FIG. 3), such that the two secondary windings 142a′, 142b′ are electrically connected in series through the upper circuit board 10. Thus, the connecting members 146a, 146b shown in FIGS. 5 and 6 may be omitted and the number of output capacitors disposed on the lower circuit board 12 may be increased.

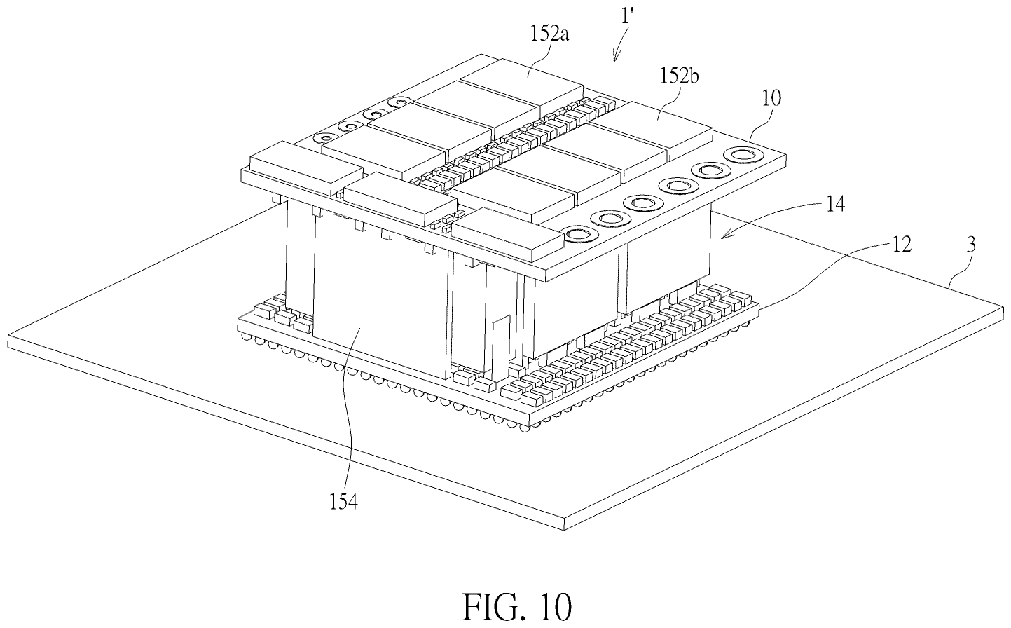

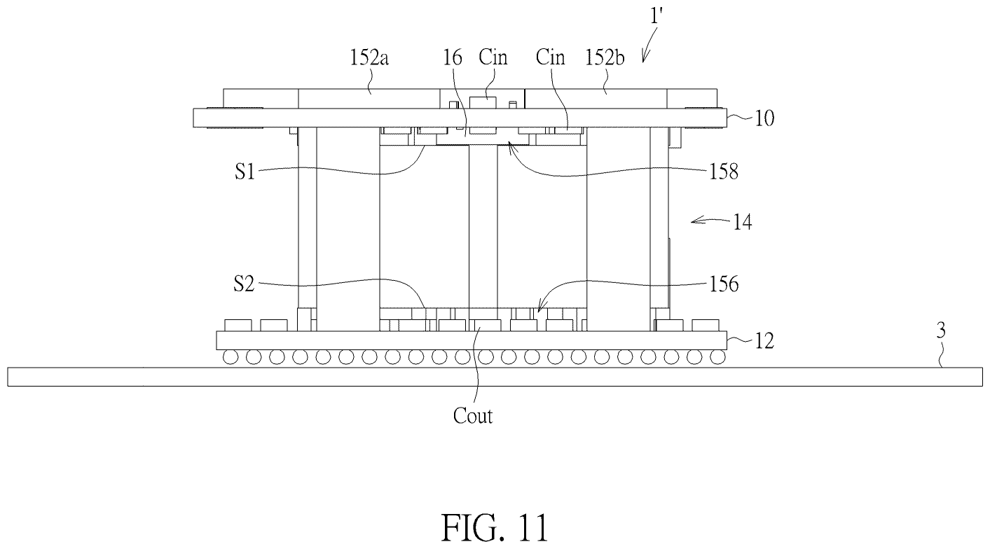

Referring to FIGS. 10 and 11, FIG. 10 is a perspective view illustrating a sub-power supply module 1′ according to another embodiment of the invention, FIG. 11 is a side view illustrating the sub-power supply module 1′ shown in FIG. 10.

As shown in FIGS. 10 and 11, the sub-power supply module 1′ further comprises a power controller 16 disposed on the upper circuit board 10. The power controller 16 transmits control signals to the power components 152a, 152b on the upper circuit board 10 through the circuit layout of the upper circuit board 10. In this embodiment, there is no control electrode disposed on the lower circuit board 12, and the control signals are only transmitted through the upper circuit board 10. Thus, the signal connecting structure 154 has fewer control signals to transmit, such that the signal connecting structure 154 may become smaller. Furthermore, a recess 158 may be formed on the upper surface S1 of the inductor 14 and configured to accommodate the input capacitors Cin. Accordingly, the input capacitors Cin may be disposed on opposite sides of the upper circuit board 10, so as to increase the number of input capacitors Cin according to practical requirements.

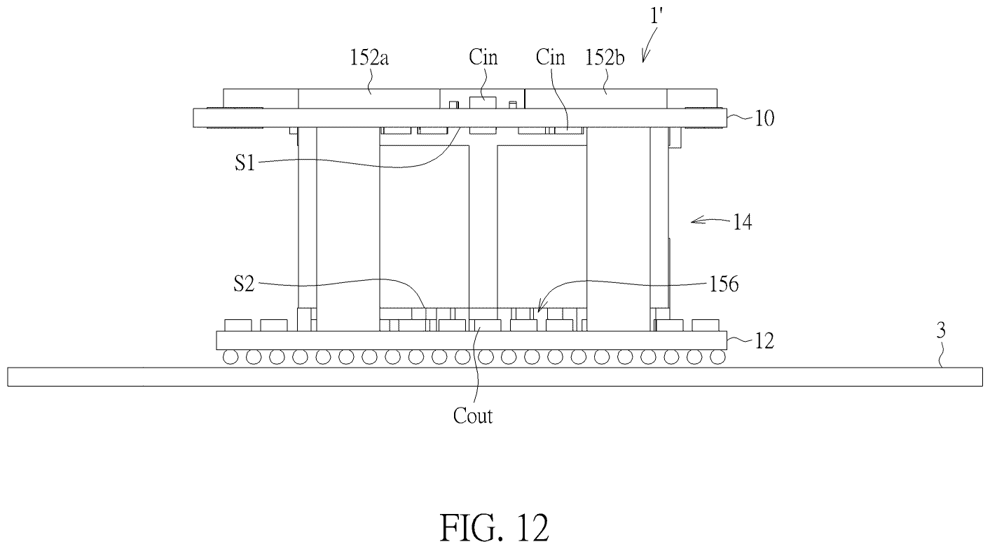

Referring to FIG. 12, FIG. 12 is a perspective view illustrating a sub-power supply module 1′ according to another embodiment of the invention.

As shown in FIG. 12, the sub-power supply module 1′ may omit the aforesaid recess 158 and a plurality of input capacitors Cin may be embedded in the upper surface S1 of the inductor 14.

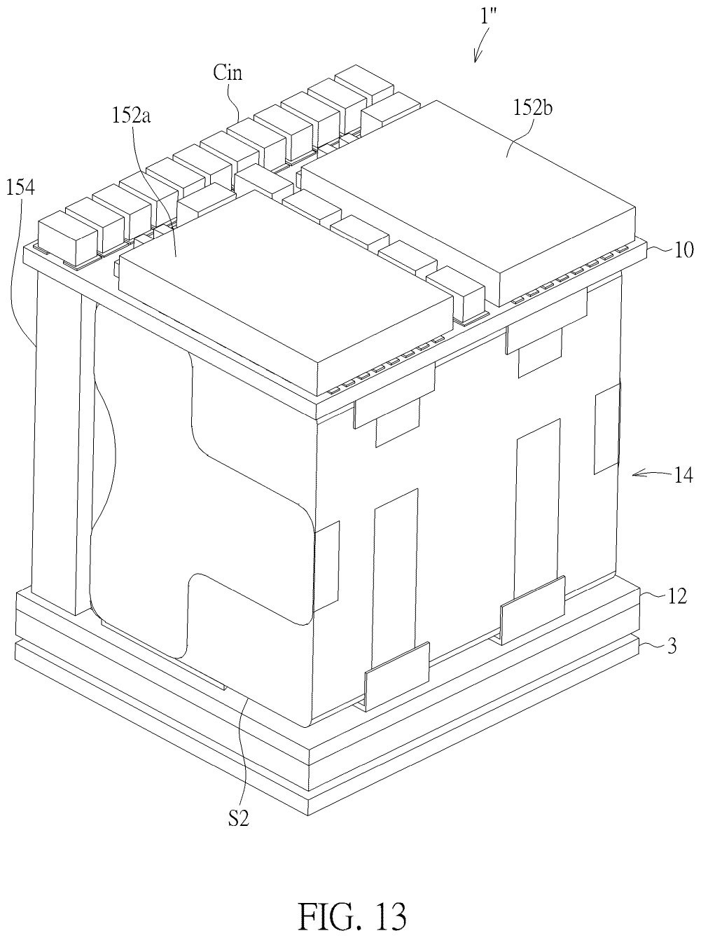

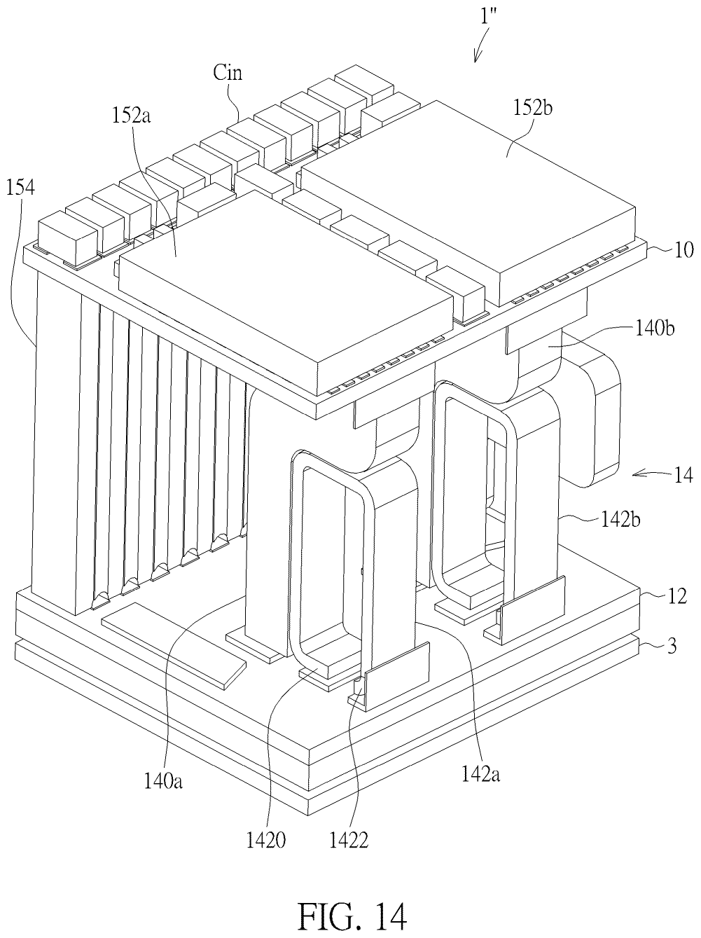

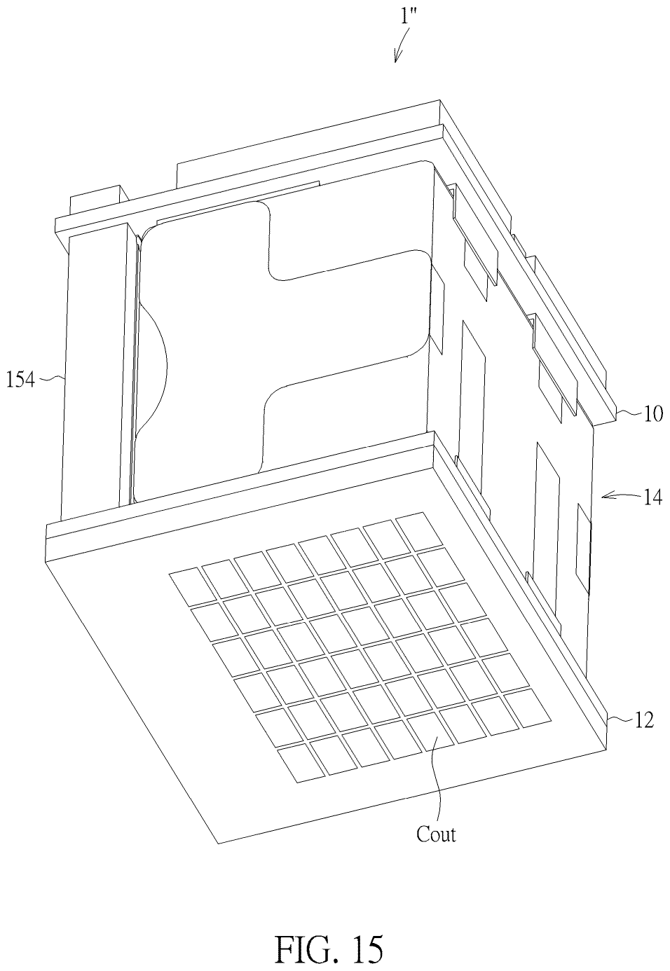

Referring to FIGS. 13 to 15, FIG. 13 is a perspective view illustrating a sub-power supply module 1″ according to another embodiment of the invention, FIG. 14 is a perspective view illustrating the inside of the sub-power supply module 1″ shown in FIG. 13, and FIG. 15 is a perspective view illustrating the sub-power supply module 1″ shown in FIG. 13 from another viewing angle.

The sub-power supply module 1′ shown in FIG. 1 may be replaced by the sub-power supply module 1″ shown in FIG. 13. The main difference between the sub-power supply module 1″ and the aforesaid sub-power supply module 1′ is that two electrodes 1420, 1422 of each of the two secondary windings 142a, 142b are arranged at the lower surface S2 of the inductor 14 and connected to the lower circuit board 12 (as shown in FIG. 14), such that the two secondary windings 142a, 142b are electrically connected in series through the lower circuit board 12 and the system board 3. In this embodiment, a plurality of output capacitors Cout may be embedded in the lower circuit board 12, as shown in FIG. 15.

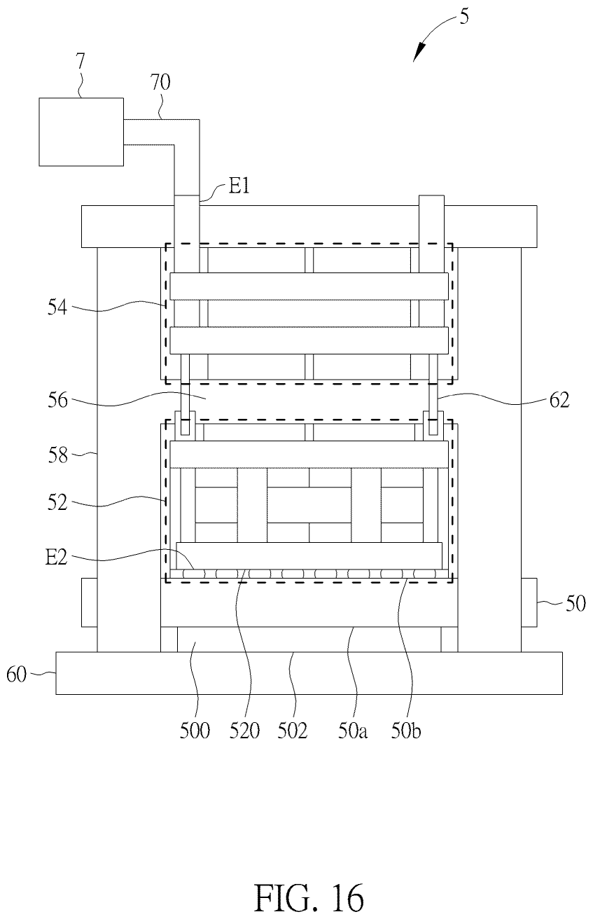

Referring to FIG. 16, FIG. 16 is a schematic view illustrating a power supply system 5 according to an embodiment of the invention.

As shown in FIG. 16, the power supply system 5 comprises a system board 50, a first-stage power supply module 52, a second-stage power supply module 54, a heat conductive structure 56, a heat dissipating structure 58 and a heat dissipating device 60. The system board 50 includes a processor 500 on a first surface 50a of the system board 50, and the first-stage power supply module 52 is disposed on a second surface 50b of the system board 50, wherein the first surface 50a is opposite to the second surface 50b. In this embodiment, the system board 50 may be a server equipped with a central processing unit (CPU), a graphics processing unit (GPU), a random access memory (RAM), a hard disk drive (HDD), solid state disk (SSD), a network interface, and so on, wherein the processor 500 may be a central processing unit (CPU), a graphics processing unit (GPU), or the like. The second-stage power supply module 54 is disposed on the first-stage power supply module 52. The heat conductive structure 56 is sandwiched between the first-stage power supply module 52 and the second-stage power supply module 54, wherein two opposite sides of the heat conductive structure 56 are respectively in contact with the first-stage power supply module 52 and the second-stage power supply module 54. Accordingly, the system board 50, the first-stage power supply module 52 and the second-stage power supply module 54 are stacked with each other in a vertical power delivery configuration, so as to reduce the path of the power distribution network (PDN) and the transient. Since the heat conductive structure 56 is sandwiched between the first-stage power supply module 52 and the second-stage power supply module 54, the heat conductive structure 56 can dissipate heat from the first-stage power supply module 52 and the second-stage power supply module 54.

The heat dissipating structure 58 is disposed outside the first-stage power supply module 52 and the second-stage power supply module 54, wherein the heat conductive structure 56 is connected to the heat dissipating structure 58. In practical applications, the heat conductive structure 56 and the heat dissipating structure 58 may be combined to be a heat dissipating mechanism, such as a cold plate, a heat pipe, a heat sink, or a combination thereof, so as to dissipate heat from the first-stage power supply module 52 and the second-stage power supply module 54.

The heat dissipating device 60 is disposed on a heat dissipating surface 502 of the processor 500 and configured to dissipate heat from the processor 500. In practical applications, the heat dissipating device 60 may be a cold plate, a heat pipe, a heat sink, or a combination thereof. The heat dissipating structure 58 may pass through the system board 50 to be connected to the heat dissipating device 60, such that the heat dissipating structure 58 may conduct heat to the heat dissipating device 60 for heat dissipation.

In this embodiment, a mounting surface 520 of the first-stage power supply module 52 is soldered to the system board 50, and the second-stage power supply module 54 and the first-stage power supply module 52 are sequentially stacked from far away from the mounting surface 520 to the mounting surface 520, such that the second-stage power supply module 54 and the first-stage power supply module 52 sequentially supply power in series. Since the first-stage power supply module 52 is stacked with the system board 50, the processor 500 and the first-stage power supply module 52 are stacked in a vertical configuration.

In this embodiment, a voltage input end E1 is only disposed on the second-stage power supply module 54 and a voltage output end E2 is only disposed on the mounting surface 520 of the first-stage power supply module 52. That is to say, there is no voltage input end disposed on the mounting surface 520 of the first-stage power supply module 52. Furthermore, a power cable 70 of a power supply unit 7 is connected to the voltage input end E1 of the second-stage power supply module 54 and a conductive pillar 62 is connected to the first-stage power supply module 52 and the second-stage power supply module 54.

During the operation of the power supply system 5, an input voltage is delivered to the voltage input end E1 of the second-stage power supply module 54 through the power cable 70. The second-stage power supply module 54 is configured to convert the input voltage into a mediate output voltage. The conductive pillar 62 is configured to deliver the mediate output voltage from the second-stage power supply module 54 to the first-stage power supply module 52. The first-stage power supply module 52 is configured to convert the mediate output voltage into a target output voltage. Then, the first-stage power supply module 52 provides the target output voltage from a plurality of power electrodes of the mounting surface 520 to the processor 500 through a circuit layout of the system board 50. In this embodiment, the first-stage power supply module 52 may be achieved by the aforesaid power supply module 1 and the repeated explanation will not be depicted herein again. Furthermore, the second-stage power supply module 54 may essentially consist of a main board, a control board, a transformer disposed between the main board and the control board, and other related components for voltage conversion.

In this embodiment, the target output voltage is smaller than the mediate output voltage, and the mediate output voltage is smaller than the input voltage. For example, the input voltage may be 48V, the mediate output voltage may be 6V, and the target output voltage may be 1V. Thus, the second-stage power supply module 54 may convert the input voltage of 48V into the mediate output voltage of 6V, and then the first-stage power supply module 52 may convert the mediate output voltage of 6V into the target output voltage of 1V. It should be noted that the input voltage, the mediate output voltage and the target output voltage may be determined according to practical applications, so the invention is not limited to the aforesaid embodiment.

As mentioned in the above, in the power supply module of the invention, two electrodes of each of the two primary windings are respectively arranged at the upper surface and the lower surface of the inductor and respectively connected to the upper circuit board and the lower circuit board, such that the power component on the upper circuit board may deliver power to the system board connected with the lower circuit board. In one embodiment, the two secondary windings may be electrically connected in series through the upper circuit board and the lower circuit board or through the upper circuit board. In another embodiment, the two secondary windings may be electrically connected in series through the lower circuit board and the system board. Through the aforesaid configuration, the two primary windings and the two power switches may form two-phase power output. Accordingly, the power supply module of the invention can be stacked with the system board by a vertical power delivery configuration, so as to reduce the path of the power distribution network (PDN) and the transient. Since the power supply module is stacked with the system board, the power delivery path is minimized to reduce the parasitic inductance and the size of the system board can also be reduced. Furthermore, in the power supply system of the invention, the system board, the first-stage power supply module and the second-stage power supply module may be stacked with each other in a vertical power delivery configuration, so as to reduce the path of the power distribution network (PDN) and the transient. Since the heat conductive structure is sandwiched between the first-stage power supply module and the second-stage power supply module, the heat conductive structure can dissipate heat from the first-stage power supply module and the second-stage power supply module.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power supply module comprising at least one sub-power supply module, each of the at least one sub-power supply module comprising:
an upper circuit board;
a lower circuit board disposed opposite to the upper circuit board, the lower circuit board having a plurality of power electrodes disposed on a mounting surface of the lower circuit board, the plurality of power electrodes being configured to be mounted to a system board; and
an inductor disposed between the upper circuit board and the lower circuit board, an upper surface of the inductor facing the upper circuit board, a lower surface of the inductor facing the lower circuit board, the inductor comprising two primary windings and two secondary windings, two electrodes of each of the two primary windings being respectively arranged at the upper surface and the lower surface of the inductor and respectively connected to the upper circuit board and the lower circuit board, the two secondary windings being electrically connected in series through the upper circuit board and the lower circuit board or through the upper circuit board.

2. The power supply module of claim 1, wherein two electrodes of each of the two secondary windings are respectively arranged at the upper surface and the lower surface of the inductor and respectively connected to the upper circuit board and the lower circuit board, the inductor further comprises two connecting members, two ends of each of the two connecting members are respectively arranged at the upper surface and the lower surface of the inductor and respectively connected to the upper circuit board and the lower circuit board, such that the two secondary windings are electrically connected in series through the upper circuit board, the lower circuit board and the two connecting members.

3. The power supply module of claim 2, wherein the two connecting members are disposed within a magnetic body of the inductor and located at two opposite sides of the magnetic body.

4. The power supply module of claim 1, wherein the inductor further comprises two power conductive members and two ends of each of the two power conductive members are respectively arranged at the upper surface and the lower surface of the inductor.

5. The power supply module of claim 4, wherein the two power conductive members are disposed within a magnetic body of the inductor and located at two opposite sides of the magnetic body.

6. The power supply module of claim 1, comprising a plurality of sub-power supply modules, wherein the lower circuit boards of the plurality of sub-power supply modules are integrated to be one single lower circuit board and the upper circuit boards of the plurality of sub-power supply modules are separated from each other.

7. The power supply module of claim 1, wherein two electrodes of each of the two secondary windings are arranged at the upper surface of the inductor and connected to the upper circuit board, such that the two secondary windings are electrically connected in series through the upper circuit board.

8. The power supply module of claim 1, wherein the sub-power supply module comprises at least one control electrode configured to receive control signals from a power component on the upper circuit board through a signal connecting structure.

9. The power supply module of claim 1, wherein the power supply module comprises a power controller disposed on the upper circuit board, the power controller transmits control signals to a power component on the upper circuit board through the upper circuit board, there is no control electrode disposed on the lower circuit board, and the control signals are only transmitted through the upper circuit board.

10. The power supply module of claim 1, wherein the inductor is a symmetrical structure.

11. The power supply module of claim 1, wherein two power switches are disposed on the upper circuit board, and the two power switches are connected in series at a switch pad to form a half bridge power component or a full bridge power component.

12. The power supply module of claim 11, wherein the switch pad is electrically connected to one of the two electrodes of the primary winding arranged at the upper surface of the inductor, the other one of the two electrodes of the primary winding arranged at the lower surface of the inductor is electrically connected to an output electrode of the lower circuit board, and one of the two primary windings and one of the two power switches form one-phase power output.

13. The power supply module of claim 1, further comprising a plurality of output capacitors, wherein the lower surface of the inductor has a recess configured to accommodate the plurality of output capacitors.

14. The power supply module of claim 1, further comprising a plurality of input capacitors embedded in the upper surface of the inductor.

15. The power supply module of claim 1, wherein the lower circuit board is equipped with a plurality of output capacitors without input capacitors and the upper circuit board is equipped with a plurality of input capacitors without output capacitors.

16. A power supply module comprising at least one sub-power supply module, each of the at least one sub-power supply module comprising:
an upper circuit board;
a lower circuit board disposed opposite to the upper circuit board, the lower circuit board having a plurality of power electrodes disposed on a mounting surface of the lower circuit board, the plurality of power electrodes being configured to be mounted to a system board; and
an inductor disposed between the upper circuit board and the lower circuit board, an upper surface of the inductor facing the upper circuit board, a lower surface of the inductor facing the lower circuit board, the inductor comprising two primary windings and two secondary windings, two electrodes of each of the two primary windings being respectively arranged at the upper surface and the lower surface of the inductor and respectively connected to the upper circuit board and the lower circuit board, two electrodes of each of the two secondary windings being arranged at the lower surface of the inductor and connected to the lower circuit board, such that the two secondary windings are electrically connected in series through the lower circuit board and the system board.

17. The power supply module of claim 16, wherein a plurality of output capacitors are embedded in the lower circuit board.
